(19) United States
(12) Patent Application Publication
(10) Pub. No.: US 2024/0224554 A1
(43) Pub. Date: Jul. 4, 2024

(54) ORGANIC ELECTROLUMINESCENT DEVICE AND DISPLAY DEVICE

(71) Applicant: BOE TECHNOLOGY GROUP CO., LTD., Beijing (CN)

(72) Inventors: Yong WU, Beijing (CN); Xiaojin ZHANG, Beijing (CN); Haiyan SUN, Beijing (CN)

(21) Appl. No.: 17/914,337

(22) PCT Filed: Oct. 28, 2021
(86) PCT No.: PCT/CN2021/127158

§ 371 Date: Sep. 24, 2022

(30) Foreign Application Priority Data
Apr. 27, 2021 (CN) 202110457279.6

(51) Int. Cl. H10K 50/11; H10K 50/18; H10K 85/60; H10K 101/10; H10K 101/30; H10K 102/00

(52) U.S. Cl. CPC H10K 50/11; H10K 50/181; H10K 85/6572; H10K 85/6574; H10K 85/658; H10K 2101/10; H10K 2101/30; H10K 2102/351

(57) ABSTRACT

The present disclosure provides an organic electroluminescent device and a display device, belonging to the field of display technology, which can solve the problem of poor luminescent efficiency and short life of the existing organic electroluminescent devices. The organic electroluminescent device of the present disclosure comprises: a first electrode and a second electrode disposed opposite to each other, and a light-emitting layer located between the first electrode and the second electrode; the light-emitting layer comprising: a first compound, a second compound and a third compound; wherein the first compound satisfies a first general formula; the third compound satisfies a second general formula; and the second compound has a difference between a triplet energy level and a singlet energy level of less than or equal to 0.3 eV.

### TECHNICAL FIELD

The present disclosure belongs to the field of display technology, and specifically relates to an organic electroluminescent device and a display device.

### BACKGROUND

An organic light-emitting device (OLED) is a kind of light-emitting device with an organic solid-state semiconductor as the light-emitting material, and has a broad application prospect because of its advantages such as simple preparation process, low cost, low power consumption, high luminous brightness, and a wide range of working temperature adaptation. By applying a voltage to the OLED, holes are injected from an anode, and electrons are injected from a cathode. The electrons and holes are combined in the light-emitting layer to form excitons, and according to the spin-statistics law, singlet excitons and triplet excitons are generated at a ratio of 25%:75%, which undergo radiation leap to realize light emission.

Currently, fluorescent OLEDs utilize singlet excitons for radiation luminescence, resulting in a theoretical limit of internal quantum efficiency (IQE) of no more than 25%, so that the efficiency of the fluorescent OLEDs is lower. Phosphorescent OLEDs utilize triplet excitons for radiation luminescence, and the quantum efficiency thereof is higher and IQE can reach 100%. However, the photoluminescence spectroscopy (PL) of the phosphorescent material has a wider half-peak width, and the triplet exciton lifetime thereof is longer, such that the exciton concentration is too high, and triplet-triplet, polariton-triplet annihilation, or the like tends to occur, resulting in a decrease in its device efficiency. Especially with the increase in current density, the exciton density increases, and the triplet-triplet, or polariton-triplet annihilation leads to a sharp decline in device efficiency. The device efficiency and efficiency roll-off problems of the OLEDs have seriously limited the development and applications thereof.

### SUMMARY

The present disclosure aims to solve at least one of the technical problems existing in the prior art and provides an organic electroluminescent device and a display device.

In a first aspect, embodiments of the present disclosure provide an organic electroluminescent device, comprising: a first electrode and a second electrode disposed opposite to each other, and a light-emitting layer disposed between the first electrode and the second electrode.

The light-emitting layer comprises: a first compound, a second compound and a third compound; wherein the first compound satisfies a first general formula; the third compound satisfies a second general formula; and the second compound has a difference between a triplet energy level and a singlet energy level of less than or equal to 0.3 eV.

The first general formula comprises:

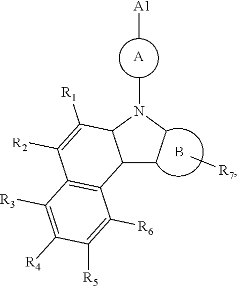

wherein the A ring denotes a substituted or unsubstituted C6 to C30 arylene group, or a substituted or unsubstituted C3 to C30 heteroarylene group;
the B ring represents phenyl, naphthyl, phenylene, naphthylene, phenanthryl, fluoranthenyl, pyridine ring, pyrazine ring, pyrimidine ring, pyridazine ring, triazine ring, substituted or unsubstituted alkyl chain, or substituted or unsubstituted C6 to C30 aryl or heteroaryl;
A1 represents phenyl, phenylene, naphthyl, naphthylene, dibenzofuran, dibenzothiophene, carbazole, pyrimidine ring, pyrazine ring, cyano, substituted or unsubstituted aryl or heteroaryl;
R1 to R7 are each independently selected from hydrogen, deuterium, a halogen group, a nitrile group, a nitro group, a hydroxyl group, a carbonyl group, an ester group, an imido group, an amino group, a substituted or unsubstituted C3 to C30 methylsilyl group, a substituted or unsubstituted boryl group, a substituted or unsubstituted C1 to C30 alkyl group, a substituted or unsubstituted C3 to C30 cycloalkyl group, a substituted or unsubstituted alkoxy group, a substituted substituted or unsubstituted aryloxy group, substituted or unsubstituted alkylthio, substituted or unsubstituted arylthio, substituted or unsubstituted alkyl sulfonyl, substituted or unsubstituted C6 to C30 aryl sulfonyl, substituted or unsubstituted alkenyl, substituted or unsubstituted aryl alkyl, substituted or unsubstituted aryl alkenyl, substituted or unsubstituted alkyl aryl, substituted or unsubstituted alkyl amino, substituted or unsubstituted C1-C30 aryl alkyl amino, substituted or unsubstituted C6-C30 heteroaryl amino, substituted or unsubstituted C6-C30 aryl amino, substituted or unsubstituted C6-C30 aryl heteroaryl amino, substituted or unsubstituted C6-C30 arylphosphinyl, a substituted or unsubstituted phosphine oxide group, a substituted or unsubstituted C6 to C30 aryl group, or a substituted or unsubstituted heterocyclic group, or a substituted or unsubstituted (C1-C30)alkylbis(C6-C30)arylmethylsilyl group;
the second general formula comprising:

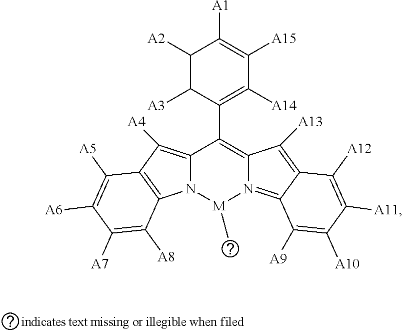

wherein M is selected from boron; n=1;
A1, A2, A3, A14, and A15 are each independently an aryl group having from 6 to 30 aromatic ring atoms, the aryl group being optionally substituted by one or more groups R1; wherein R1 may be an aldehyde group, a carbonyl group, a carboxyl group, a halogen atom, a sulfonic acid group, a haloalkyl group, a cyano, a nitro, a tertiary amino group, a cyano, a nitro, a formyl, an acyl, a thiophene, a dibenzothiophene, a furan, a dibenzofuran, a cycloalkyl, aromatic alkynyl, a heterocyclic group, halogen atom, alkoxy, aryl alkyl, methylsilyl, carboxyl, aryloxy, substituted amino, benzene, naphthalene, anthracene, phenanthrene, pyrene, fluoranthene, dihydropyrene, benzanthracene, isobenzothiophene, thiofluorene, pyrrole, indole, isoindole, carbazole, pyridine, quinoline, isoquinoline, acridine, phenanthridine, benzoquinoline, or thienozine, phenoxazine;
A5-A8, and A9-A12 are each independently a linear alkyl group having 1 to 10 carbon atoms, a branched or cyclic alkyl group having 3 to 10 carbon atoms, an alkenyl group, an alkynyl group, a substituted cycloalkyl group, an aromatic group, a substituted aromatic group, a fused ring aromatic group, a substituted fused ring aromatic group, a heterocyclic group, a substituted heterocyclic group; and
A4 and A13 are selected from linear or branched alkyl groups having from 1 to 10 carbon atoms, aromatic or heteroaromatic or fused rings having from 6 to 30 ring atoms.

Optionally, the organic electroluminescent device further comprises: an exciton separation layer on a side of the light emitting layer close to the first electrode.

The exciton separation layer comprises: a fourth compound and a fifth compound; the fourth compound satisfying the first general formula; and the fifth compound having a difference between a triplet energy level and a singlet energy level of less than or equal to 0.3 eV.

Optionally, the overlap area between an emission spectrum of the first compound and an absorption spectrum of the second compound is greater than 5%.

The overlap area between an emission spectrum of the second compound and the absorption spectrum of the third compound is greater than 5%.

Optionally, the overlap area between the emission spectrum of the fourth compound and the absorption spectrum of the fifth compound is greater than 5%.

Optionally, the organic electroluminescent device further comprises: a hole injection layer, a hole transport layer and an electron blocking layer disposed sequentially between the first electrode and the exciton separation layer in a direction away from the first electrode, and an electron injection layer, an electron transport layer and a hole blocking layer disposed sequentially between the second electrode and the light emitting layer in a direction away from the second electrode.

Optionally, the third compound has a triplet energy level lower than the triplet energy level of the second compound.

The triplet energy level of the second compound is lower than the triplet energy level of the first compound.

The first compound has a triplet energy level lower than the triplet energy level of the material of the electron-blocking layer or the triplet energy level of the material of the hole-blocking layer.

Optionally, the fifth compound has a triplet energy level lower than the triplet energy level of the fourth compound.

The fourth compound has a triplet energy level lower than the triplet energy level of the material of the electron-blocking layer or the triplet energy level of the material of the hole-blocking layer.

Optionally, the absolute value of the LUMO energy level of the material of the electron-blocking layer differs from the absolute value of the LUMO energy level of the fourth compound by 0.3 eV or less.

Optionally, the absolute value of the HOMO energy level of the material of the hole-blocking layer differs from the absolute value of the HOMO energy level of the third compound by more than 0.3 eV.

Optionally, the light emitting layer has a thickness of less than or equal to 22 nm.

The exciton separation layer has a thickness of less than or equal to 3 nm.

Optionally, the doping ratio of the first compound to the second compound is 80%:20% to 60%:40%.

The doping ratio of the fourth compound to the fifth compound is 80%:20% to 60%:40%.

Optionally, the organic electroluminescent device further comprises: a light extraction layer located on a side of the second electrode away from the first electrode.

In a second aspect, embodiments of the present disclosure provide a display device comprising an organic electroluminescent device as provided above.

### BRIEF DESCRIPTION OF DRAWINGS

FIG. 1 is a schematic diagram of the structure of an organic electroluminescent device provided by embodiments of the present disclosure;

FIG. 2 is a schematic diagram of the structure of another organic electroluminescent device provided by embodiments of the present disclosure;

FIGS. 3 to 42 show a molecular structure of a first compound in an organic electroluminescent device, respectively;

FIGS. 43 to 74 show a molecular structure of a third compound in an organic electroluminescent device, respectively; and

FIGS. 75 to 85 show molecular structures of the compounds corresponding to the respective film layers in the organic electroluminescent device.

### DESCRIPTION OF EMBODIMENTS

To enable those skilled in the art to better understand the technical embodiments, the present disclosure will be described in detail below with reference to the accompanying drawings and specific embodiments.

Unless otherwise defined, the technical or scientific terms used in this disclosure shall have the ordinary meanings as understood by those skilled in the art to which this disclosure pertains. The terms “first”, “second” and the like as used in this disclosure do not indicate any order, number, or importance, but are used only to distinguish different components. Similarly, the word “a”, “an” or “the” and similar words do not indicate a numerical limitation, but rather the presence of at least one. The term “include” or “comprise” and similar terms are intended to mean that the components or objects appearing before the terms encompass the components or objects listed thereafter and their equivalents, and do not exclude the presence of other components or objects. The term “connected” or “linked” and similar terms are not limited to physical or mechanical connections, but may include electrical connections, either direct or indirect. The terms “up”, “down”, “left”, “right”, and the like are used only to indicate relative position relationship, and when the absolute position of the object being described is changed, the relative position relationship may also be changed accordingly.

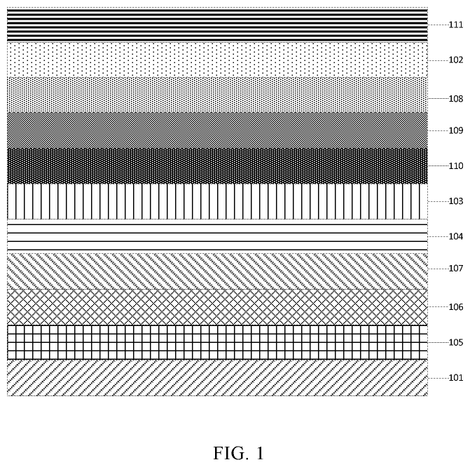

In the first aspect, an embodiment of the present disclosure provides an organic electroluminescent device. FIG. 1 shows a schematic structure of the organic electroluminescent device provided by the embodiment of the disclosure. As shown in FIG. 1, the organic electroluminescent device includes: a first electrode 101 and a second electrode 102 disposed opposite to each other, and a light-emitting layer 103 located between the first electrode 101 and the second electrode 102; wherein the light-emitting layer 103 comprises: the first compound, the second compound and the third compound; wherein the first compound satisfies the first general formula; the third compound satisfies the second general formula; and the difference between the triplet energy level and the singlet energy level of the second compound is less than or equal to 0.3 eV.

The first general formula comprises:

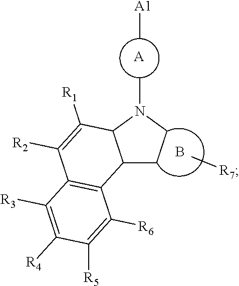

wherein the A ring denotes a substituted or unsubstituted C6 to C30 arylene group, or a substituted or unsubstituted C3 to C30 heteroarylene group; the B ring denotes phenyl, naphthyl, phenylene, naphthylene, phenanthryl, fluoranthenyl, pyridine ring, pyrazine ring, pyrimidine ring, pyridazine ring, triazine ring, substituted or unsubstituted alkyl chain, or substituted or unsubstituted C6 to C30 aryl or heteroaryl; A1 denotes phenyl, phenylene, naphthyl, naphthylene, dibenzofuran, dibenzothiophene, carbazole, pyrimidine ring, pyrazine ring, cyano, substituted or unsubstituted aryl or heteroaryl; R1 to R7 are each independently selected from hydrogen, deuterium, a halogen group, a nitrile group, a nitro group, hydroxyl, carbonyl, ester, imido, amino, substituted or unsubstituted C3 to C30 methylsilyl, substituted or unsubstituted boryl, substituted or unsubstituted C1 to C30 alkyl, substituted or unsubstituted C3-C30 cycloalkyl, substituted or unsubstituted alkoxy, substituted or unsubstituted aryloxy, substituted or unsubstituted alkylthio, substituted or unsubstituted arylthio, substituted or unsubstituted alkyl sulfonyl, substituted or unsubstituted C6-C30 aryl sulfonyl, substituted or unsubstituted alkenyl, substituted or unsubstituted aryl alkyl, substituted or unsubstituted aryl alkenyl, substituted or unsubstituted alkyl aryl, substituted or unsubstituted alkyl amino, substituted or unsubstituted C1 to C30 aryl alkyl amino, substituted or unsubstituted C6 to C30 heteroaryl amino, substituted or unsubstituted C6 to C30 aryl amino, substituted or unsubstituted C6-C30 aryl heteroarylamino, substituted or unsubstituted C6-C30 arylphosphinyl, a substituted or unsubstituted phosphine oxide group, a substituted or unsubstituted C6-C30 aryl group, or a substituted or unsubstituted heterocyclic group, or a substituted or unsubstituted (C1-C30)alkylbis(C6-C30)arylmethylsilyl group. The second general formula comprises:

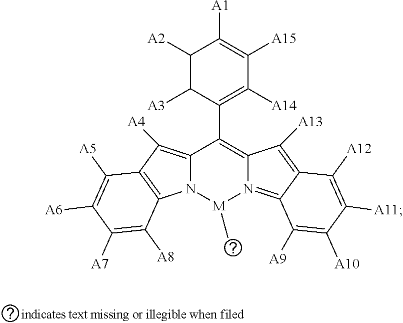

wherein M is selected from boron; n=1; A1, A2, A3, A14, and A15 are each independently an aryl group having from 6 to 30 aromatic ring atoms, the aryl group being optionally substituted by one or more groups R1; wherein R1 may be an aldehyde group, carbonyl group, carboxyl group, halogen atom, sulfonic acid group, haloalkyl group, cyano, nitro, tertiary amino group, cyano, nitro, formyl group, acyl group, thiophene, dibenzothiophene, furan, dibenzofuran, cycloalkyl, aromatic alkynyl, heterocyclic group, halogen atom, alkoxy, aryl alkyl, methylsilyl, carboxyl, aryloxy, substituted amino, benzene, naphthalene, anthracene, phenanthrene, pyrene, fluoranthene, dihydropyrene, benzanthracene, isobenzothiophene, thiofluorene, pyrrole, indole, isoindole, carbazole, pyridine, quinoline, isoquinoline, acridine, phenanthridine, benzoquinoline, thienozine, or phenoxazine; A5-A8, and A9-A12 are each independently a linear alkyl group having 1 to 10 carbon atoms, a branched or cyclic alkyl group having 3 to 10 carbon atoms, an alkenyl group, an alkynyl group, a substituted cycloalkyl group, an aromatic group, a substituted aromatic group, a fused ring aromatic group, a substituted fused ring aromatic group, a heterocyclic group, a substituted heterocyclic group; A4, and A13 are selected from a linear or branched alkyl group having 1 to 10 carbon atoms, an aromatic ring or heteroaromatic ring or fused ring having 6 to 30 ring atoms.

The organic light-emitting device may be formed on a substrate (not shown in the figure). The substrate may be made of either flexible or rigid transparent materials, which specifically may be glass, polyimide, thermoplastic polyester, metal film, etc. The materials of the substrate may be chosen as desired, which are not listed exhaustively here.

The first electrode 101 may be an anode of the organic electroluminescent device, and the anode may be made from a high power function electrode material. The anode may be a single-layer structure, or a multi-layer composite structure. For example, the anode may be made of transparent materials such as indium tin oxide (ITO) and indium zinc oxide (IZO), or may be formed from a metal material having good conductivity and sandwiched between two layers of indium tin oxide (ITO). The metal material may be any one of aluminum (A1), silver (Ag), titanium (Ti), molybdenum (Mo), or any alloys thereof.

The second electrode 102 has a polarity opposite to that of the first electrode 101 and may be a cathode of the organic electroluminescent device. The cathode may be made of metal materials. For example, the cathode may be made of any one of metal materials such as lithium (Li), aluminum (A1), magnesium (Mg), silver (Ag), or any alloys thereof.

When a voltage is applied between the first electrode 101 and the second electrode 102, holes and electrons are introduced into the light emitting layer 103, and excitons are formed in the layer 103. The excitons as formed can undergo an energy level jump in the light emitting layer 103, releasing energy for luminescence. The light-emitting layer 103 consists of a first compound, a second compound, and a third compound, wherein the first compound may be considered as a host material, the third compound may be considered as a guest material, and the second compound may be considered as a collocation material.

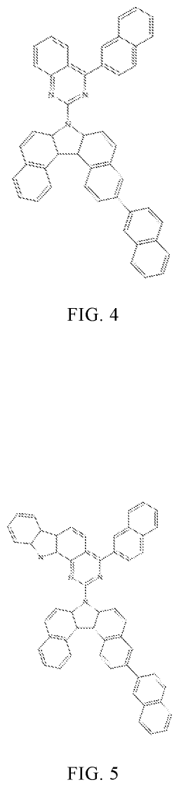

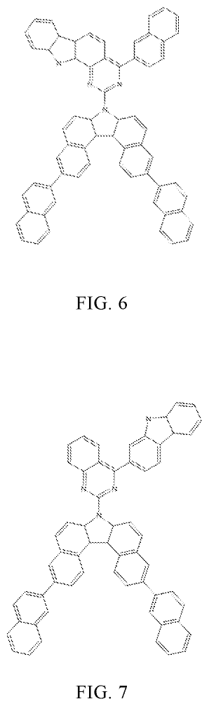

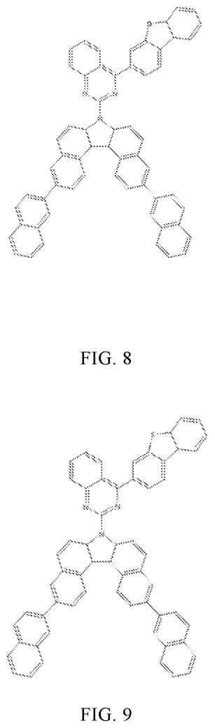

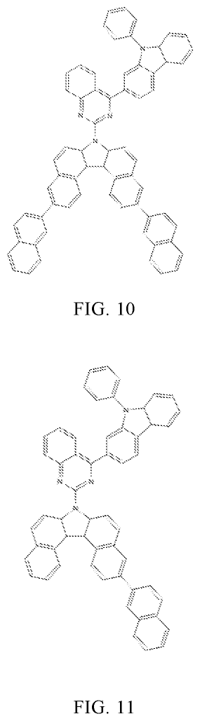

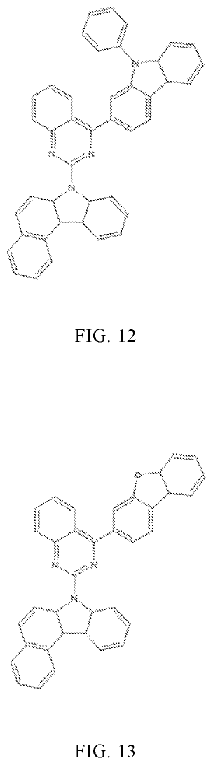

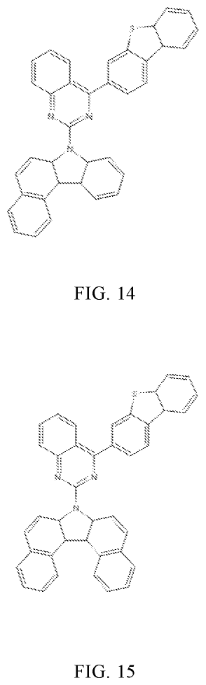

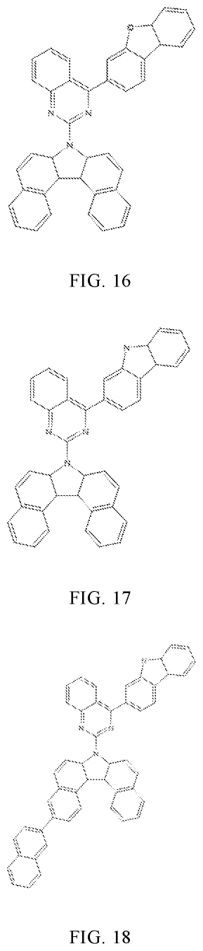

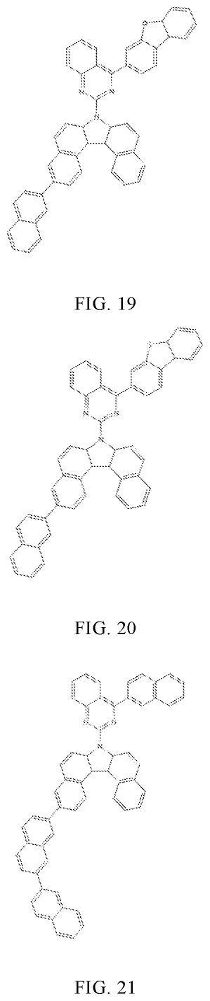

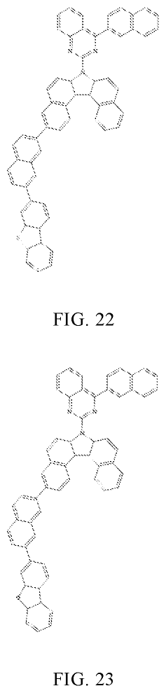

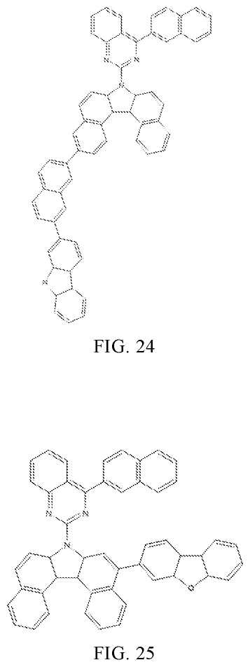

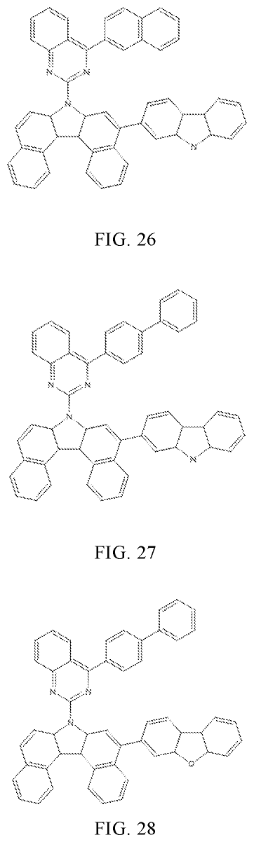

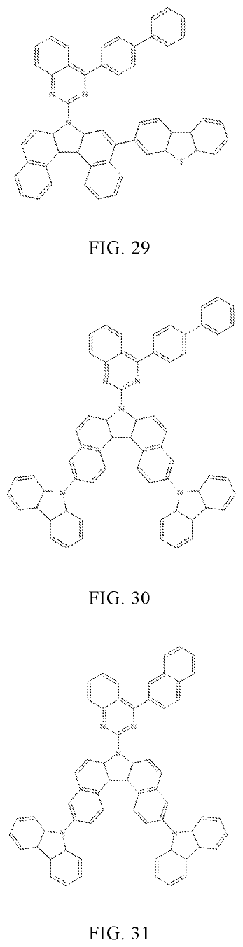

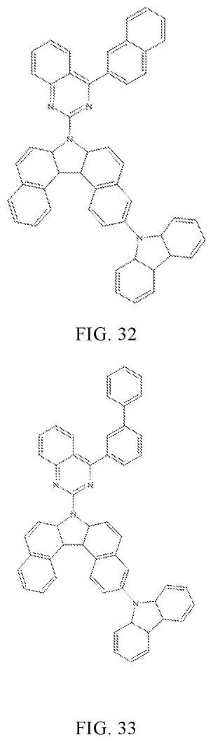

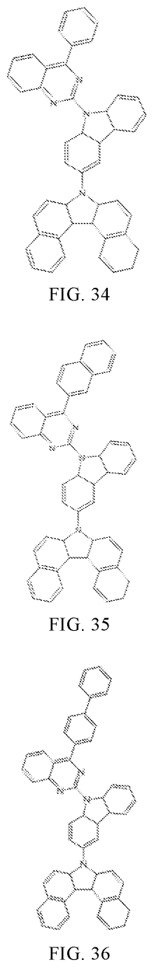

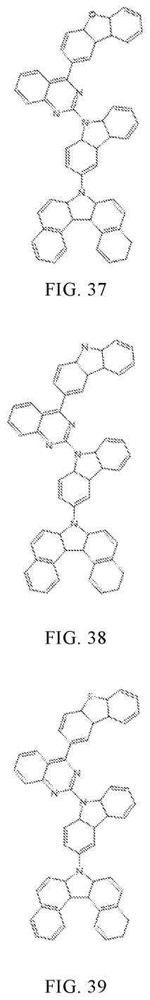

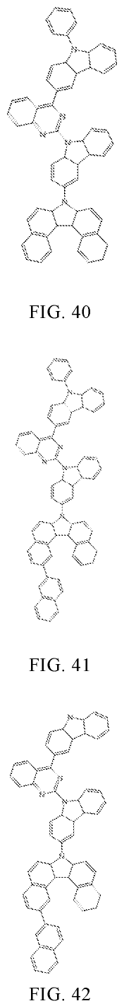

The first compound satisfies the first general formula described above, and specifically, the molecular structure of the first compound may include, but is not limited to, any one of the molecular structures as shown in FIGS. 3 to 42.

The excited state energy level of the second compound satisfies: S1−T1≤0.3 eV; wherein, S1 denotes a triplet energy level and T1 denotes a singlet energy level. The difference between the triplet energy level and the singlet energy level of the second compound is less than or equal to 0.3 eV, which can facilitate efficient transfer of the exciton energy to improve the efficiency of the organic electroluminescent device and reduce the roll-off of the light-emitting device.

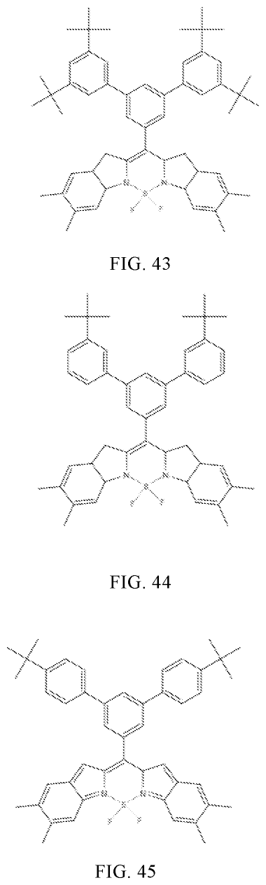

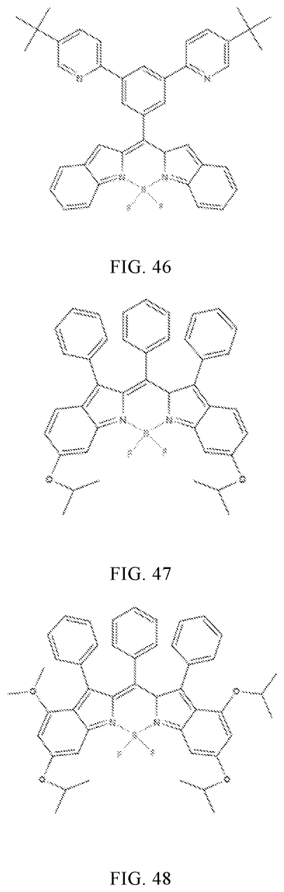

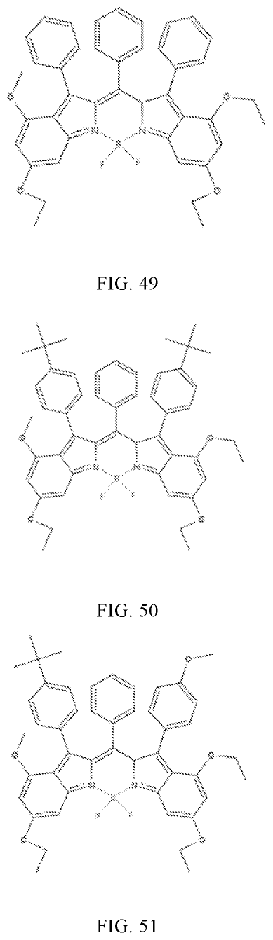

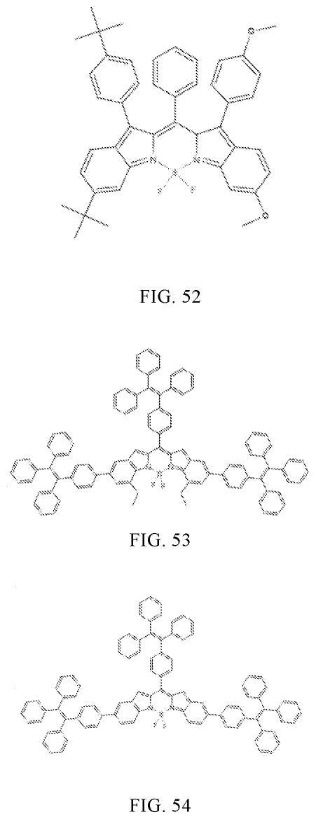

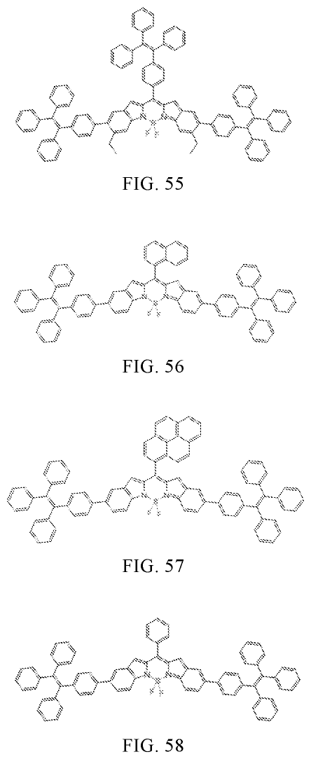

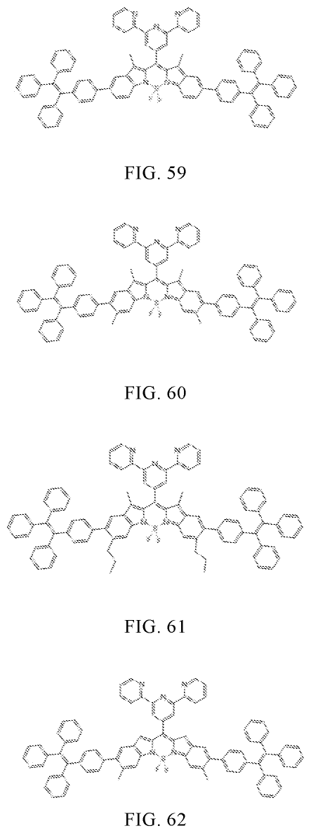

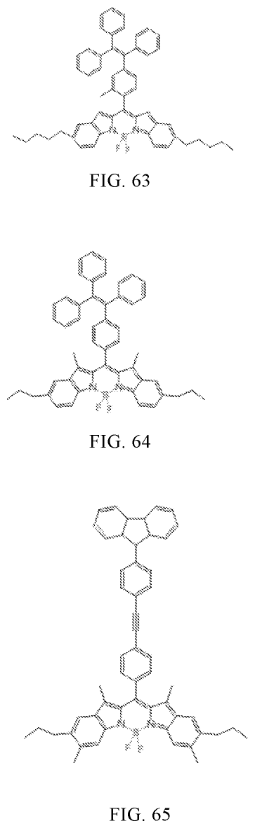

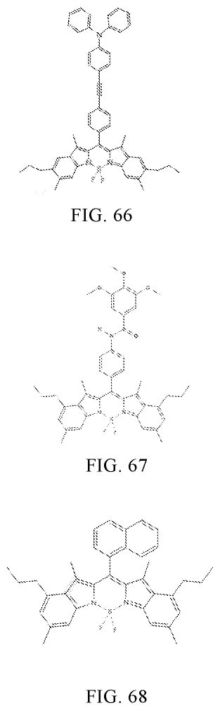

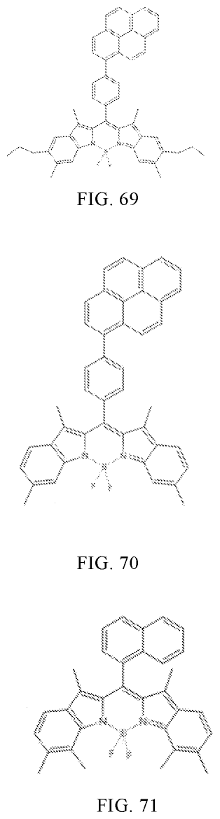

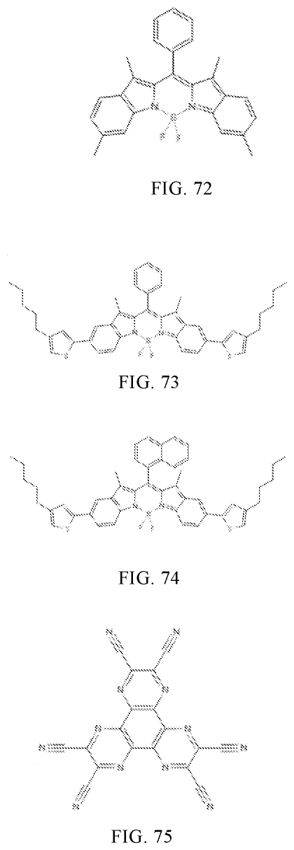

The third compound satisfies the second general formula described above, and specifically, the molecular structure of the second compound may include, but is not limited to, any one of the molecular structures as shown in FIGS. 43 to 74.

In the organic electroluminescent device provided in the embodiments of the present disclosure, the light-emitting layer 103 may comprise a first compound, a second compound and a third compound, wherein the first compound may be any one of the above compounds satisfying the first general formula, and the third compound may be any one of the above compounds satisfying the second general formula. The second compound may be a thermally activated delayed doping material (TADF), a difference between a triplet energy level and a singlet energy level thereof being less than or equal to 0.3 eV. In practical applications, the first compound, the second compound and the third compound can be mixed at a certain ratio, which can improve the exciton energy transfer efficiency between the first compound and the third compound in the light-emitting layer 103, and which can improve the luminescence efficiency of the organic electroluminescent device and reduce the roll-off of the organic electroluminescent device. In addition, the light-emitting layer 103 may consist of the first compound, the second compound and the third compound, which can effectively improve the stability of the light-emitting layer 103 and can improve the service life of the organic electroluminescent device, thus improving the user experience.

In some embodiments, the organic electroluminescent device further comprises: an exciton separation layer 104 located on a side of the light-emitting layer 103 close to the first electrode 101; the exciton separation layer comprising: a fourth compound and a fifth compound; wherein the fourth compound satisfies the first general formula; and the fifth compound has a difference between a triplet energy level and a singlet energy level of less than or equal to 0.3 eV.

The exciton separation layer 104 may be disposed by laminating with the light-emitting layer and comprises a fourth compound and a fifth compound. The fourth compound satisfies the first general formula described above, and the fifth compound has a difference between the triplet energy level and the singlet energy level of less than or equal to 0.3 eV. Specifically, the fourth compound may be the same material as the first compound and the fifth compound may be the same material as the second compound. The exciton separation layer 104 differs from the light-emitting layer in that the exciton separation layer 104 does not contain the third compound, so that the exciton separation layer 104 itself does not emit light. Since the fifth compound has a difference between the triplet energy level and the singlet energy level of less than or equal to 0.3 eV and has the property of forming triplet excitons within it and forming singlet excitons through the reverse inter-system crossing, the exciton separation layer 104 in the organic electroluminescent device can also form excitons and the exciton energy is transferred from the triplet energy level to the triplet energy level in the exciton separation layer 104 by Forster energy transfer (FET) with less energy loss, and thus the Dexter energy transfer (DET) between the triplet energy level with high energy consumption is effectively suppressed. So, the energy transfer efficiency can be improved, which in turn can improve the luminescence efficiency of the organic electroluminescent device and reduce the roll-off of the organic electroluminescent device. In addition, due to the presence of the exciton separation layer 104, the exciton energy can be transferred to the light-emitting layer 103, which can further effectively improve the stability of the light-emitting layer 103, and thus can improve the service life of the organic electroluminescent device, and in turn, can improve the user experience. It can be understood that the fourth compound may be a material different from the first compound and the fifth compound may also be a material different from the second compound, as long as the fourth compound and the fifth compound can meet the performance of exciton formation and energy transfer, the principle of which is the same as that described above and will not be repeated here.

When the first compound in the light-emitting layer 103 has an electron mobility greater than the hole mobility (that is, the first compound in the light-emitting layer 103 is an electron-type material), electrons will easily be transferred from the side of the second electrode 102 to the side of the first electrode 101 through the light-emitting layer 103. Therefore, the exciton separation layer 104 can be disposed at the side of the light-emitting layer 103 close to the first electrode 101, which will facilitate combining of the electrons and holes in the exciton separation layer 104 to achieve a desired exciton density, so that the excitons formed in exciton separation layer 104 can be effectively transferred to the light-emitting layer, which can improve the luminescence efficiency of the organic electroluminescent device and reduce the roll-off of the organic electroluminescent device.

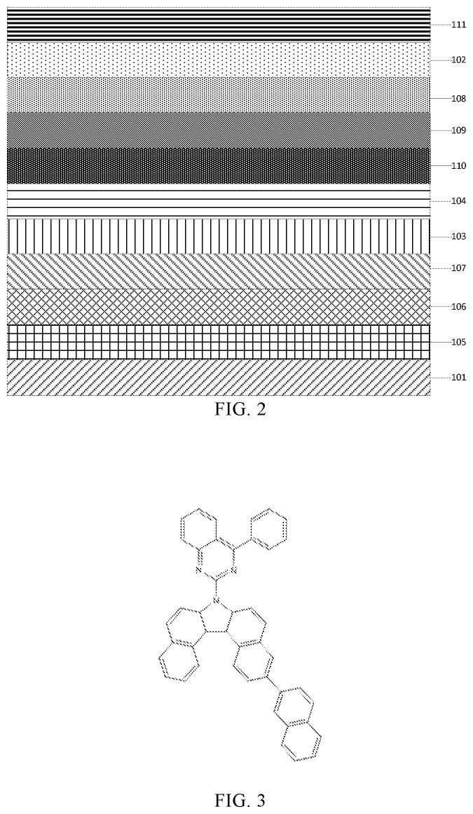

When the first compound in the light-emitting layer 103 has a hole mobility greater than the electron mobility (that is, the first compound in the light-emitting layer 103 is a hole-type material), holes will easily be transferred from the side of the first electrode 101 to the side of the second electrode 102 through the light-emitting layer 103. So, the exciton separation layer 104 may be disposed at the side of the light-emitting layer close to the second electrode 102 (as shown in FIG. 2), which will facilitate combining of the electron and holes in the exciton separation layer 104 to achieve a desired exciton density, so that the excitons formed in the exciton separation layer 104 can be effectively transferred to the light-emitting layer, which can improve the luminescence efficiency of the organic electroluminescent device and reduce the roll-off of the organic electroluminescent device.

In some embodiments, the overlap area between the emission spectrum of the first compound and the absorption spectrum of the second compound is greater than 5%. The overlap area between the emission spectrum of the second compound and the absorption spectrum of the third compound is greater than 5%.

In practical applications, the larger the overlap area between the emission spectrum of the first compound and the absorption spectrum of the second compound (the higher the overlap), the more favorable the transfer of exciton energy from the first compound to the second compound, and similarly, the larger the overlap area between the emission spectrum of the second compound and the absorption spectrum of the third compound (the higher the overlap), the more favorable the transfer of exciton energy from the second compound to the third compound. In the embodiment of the present disclosure, the overlap area between the emission spectrum of the first compound and the absorption spectrum of the second compound is greater than 5%, and the overlap area between the emission spectrum of the second compound and the absorption spectrum of the third compound is greater than 5%, which can facilitate the transfer of exciton energy in the first compound to the second compound, and the transfer of exciton energy in the second compound to the third compound, such that the luminescence efficiency of the organic electroluminescent device can be improved and the roll-off of the organic electroluminescent device can be reduced.

In some embodiments, the overlap area of the emission spectrum of the fourth compound and the absorption spectrum of the fifth compound is greater than 5%.

It should be noted here that the overlap area of the emission spectrum of the fourth compound and the absorption spectrum of the fifth compound is greater than 5%, which can facilitate the transfer of exciton energy in the fourth compound to the fifth compound, such that the luminescence efficiency of the organic electroluminescent device can be improved and the roll-off of the organic electroluminescent device can be reduced.

In some embodiments, the organic electroluminescent device further comprises: a hole injection layer 105, a hole transport layer 106 and an electron blocking layer 107 disposed sequentially between the first electrode 101 and the exciton separation layer 104 in a direction away from the first electrode 101, and an electron injection layer 108, an electron transport layer 109 and a hole blocking layer 110 disposed sequentially between the second electrode 102 and the light-emitting layer 103 in a direction away from the second electrode 102.

The main role of the hole injection layer 105 is to reduce the hole injection barrier and improve the hole injection efficiency, which can adopt a monolayer film structure prepared from injection materials such as HATCN and CuPc, or can be prepared by P-type doping in the hole transport material, for example, NPB: F4TCNQ, TAPC: MnO3, etc. The concentration of the P-type doping is generally 0.5% to 10%. The thickness of the hole injection layer 105 may be from 5 nm to 20 nm and can be formed by a co-evaporation process.

The hole transport layer 106 has good hole transport properties and can be made from materials such as NPB, m-MTDATA, TPD, TAPC, etc. The thickness of the hole transport layer 106 may be from 10 nm to 2000 nm and may be formed by a vapor deposition process.

The hole mobility of the electron blocking layer 107 is generally 1 to 2 orders of magnitude greater than the electron mobility, and it is mainly used to transfer holes. The electron blocking layer 107 can effectively block the electron transport, and can be made from TCTA or other materials. The thickness of the electron blocking layer 107 may be 5 nm to 100 nm.

The electron injection layer 108 is made from materials such as LiF, Yb and LiQ. The electron injection layer 108 may have a thickness of from 1 nm to 10 nm.

The electron transport layer 109 has good electron transport properties and may be made from materials such as TmPyPB, B4PyPPM, etc. The electron transport layer 109 may have a thickness of from 20 nm to 100 nm.

The hole-blocking layer 110 has an electron mobility which is generally 1 to 2 orders of magnitude greater than the hole mobility, and it is mainly used to transfer electrons. The hole-blocking layer 110 can effectively block the transmission of holes, and can be made from materials such as BCP, TPBI, TBB, TBD, etc. The hole-blocking layer 110 can have a thickness of 5 nm to 100 nm.

In some embodiments, the third compound has a triplet energy level lower than the triplet energy level of the second compound; the triplet energy level of the second compound is lower than the triplet energy level of the first compound; and the triplet energy level of the first compound is lower than the triplet energy level of the material of the electron-blocking layer or the triplet energy level of the material of the hole-blocking layer.

It should be noted that the third compound has a triplet energy level lower than the triplet energy level of the second compound, the triplet energy level of the second compound is lower than the triplet energy level of the first compound, and the triplet energy level of the first compound is lower than the triplet energy level of the material of the electron-blocking layer or the triplet energy level of the material of the hole-blocking layer, which can ensure that the exciton energy is transferred in the light-emitting layer 103 and avoid the transfer of exciton energy from the light-emitting layer 103 to the adjacent electron-blocking layer 107 or the hole-blocking layer 110, thereby facilitating the efficient transfer of the exciton energy to improve the efficiency of the organic electroluminescent device and reduce the roll-off of the light-emitting device. In some embodiments, the fifth compound has a triplet energy level lower than the triplet energy level of the fourth compound; and the triplet energy level of the fourth compound is lower than the triplet energy level of the material of the electron-blocking layer or the triplet energy level of the material of the hole-blocking layer.

It should be noted that the fifth compound has a triplet energy level lower than the triplet energy level of the fourth compound, and the triplet energy level of the fourth compound is lower than the triplet energy level of the material of the electron blocking layer or the triplet energy level of the material of the hole blocking layer, which can ensure the transfer of exciton energy in the exciton separation layer 104 and avoid the transfer of exciton energy from the exciton separation layer 104 to the adjacent electron blocking layer 107 or the hole blocking layer 110. This can facilitate the efficient transfer of the exciton energy to improve the efficiency of the organic electroluminescent device and reduce the roll-off of the light-emitting device.

In some embodiments, the difference between the absolute value of the LUMO energy level of the material of the electron-blocking layer 107 and the absolute value of the LUMO energy level of the fourth compound is less than or equal to 0.3 eV.

It should be noted that the difference between the absolute value of the LUMO energy level of the material of the electron-blocking layer 107 and the absolute value of the LUMO energy level of the fourth compound is less than or equal to 0.3 eV, which can ensure that the exciton energy is transferred in the exciton separation layer 104 and avoid the transfer of exciton energy from the exciton separation layer 104 to the adjacent electron-blocking layer 107. This can facilitate the efficient transfer of exciton energy to improve the efficiency of the organic electroluminescent device and reduce the roll-off of the light-emitting device.

In some embodiments, the difference between the absolute value of the HOMO energy level of the material of the hole-blocking layer 110 and the absolute value of HOMO energy level of the third compound is greater than 0.3 eV.

It should be noted that the difference between the absolute value of the HOMO energy level of the material of the hole-blocking layer 110 and the absolute value of HOMO energy level of the third compound is greater than 0.3 eV, which can ensure the transfer of the exciton energy in the light-emitting layer 103 and avoid the transfer of the exciton energy from the light-emitting layer 103 to the adjacent hole-blocking layer 110. This can facilitate the efficient transfer of the exciton energy to improve the efficiency of the organic electroluminescent device and reduce the roll-off of the light-emitting device.

In some embodiments, the light-emitting layer 103 has a thickness of less than or equal to 22 nm; the exciton separation layer 104 has a thickness of less than or equal to 3 nm.

In some embodiments, the doping ratio of the first compound to the second compound is 80%:20% to 60%:40%. The doping ratio of the fourth compound to the fifth compound is 80%:20% to 60%:40%.

It should be noted here that the thickness of the light-emitting layer 103 and the exciton separation layer 104, as well as the doping ratios of the compounds therein can be set appropriately according to practical needs with reference to the above parameters, which will be described in the subsequent collection of tables, and are not described in detail here.

In some embodiments, the organic electroluminescent device further comprises: a light extraction layer 111 on the side of the second electrode away from the first electrode 101.

The light extraction layer 111 may be made from a small-molecular organic material, such as NPB (N,N′-bis(1-naphthyl)-N,N′-diphenyl-1,1′-biphenyl-4,4′-diamine), CBP (4,4′-bis(N-carbazolyl)-1,1′-biphenyl), etc. The light extraction layer 111 has a higher refractive index and can make the light passing through the second electrode 102 refract and reflect in a variety of directions to reduce the probability of total reflection at the interface between the second electrode 102 and the light extraction layer 111, thereby increasing the light extraction rate and thus improving the luminescence efficiency of the organic electroluminescent device.

The performances of the organic electroluminescent device provided by the embodiments of the present disclosure will be further described below with reference to specific exemplary organic electroluminescent devices and comparative examples.

Example 1: the structure of each film layer in the organic electroluminescent device is set in accordance with the following parameters, with film thickness in parentheses (unit: nm).

Cavity injection layer: HIL (10);

Hole transport layer: HTL (100);

Electron-blocking layer: EBL (5);

Exciton separation layer: Compound 1-1: TH=80%: 20% (3);

Light emitting layer: Compound 1-1: TH: Compound 2-1=70%: 30%: 1% (22);

Hole-blocking layer: HBL (5);

Electron transport layer: ETL (40);

Electron injection layer: EIL (1);

Cathode: Mg:Ag (8:2) (100);

Light extraction layer: CPL (65).

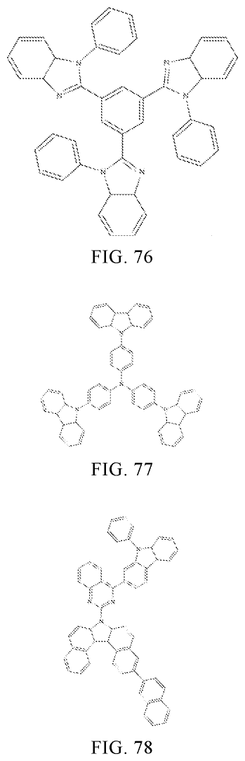

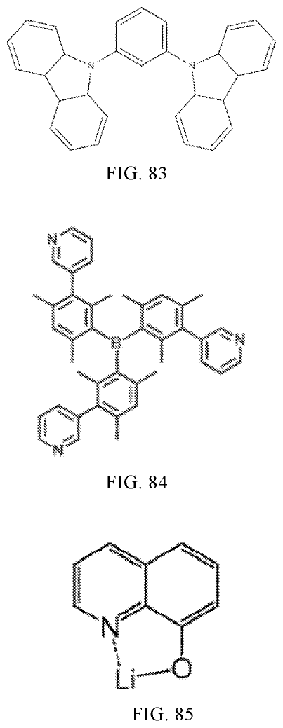

Among them, the molecular structure of the material used for the hole injection layer is shown in FIG. 75, the molecular structure of the material used for the hole transport layer is shown in FIG. 76, the molecular structure of the material used for the electron blocking layer is shown in FIG. 77, the molecular structure of Compound 1-1 used for the exciton separation layer and the light-emitting layer is shown in FIG. 78, the molecular structure of Compound 2-1 used for the light-emitting layer is shown in FIG. 81, and the molecular structure of Compound TH used in the light emitting layer is shown in FIG. 80, the molecular structure of the material used in the hole-blocking layer is shown in FIG. 83, the molecular structure of the material used in the electron transport layer is shown in FIG. 84, and the molecular structure of the material used in the electron injection layer is shown in FIG. 85.

Comparative Example 1: the organic electroluminescent device is prepared in the same manner as Example 1, except that the exciton separation layer is removed, and the thickness of the light-emitting layer is increased to 25 nm.

Comparative Example 2: the organic electroluminescent device is prepared in the same manner as Example 1, except that Compound 2-1 in the light-emitting layer is replaced with a conventional light-emitting material RD. The molecular structure of the conventional light-emitting material RD is shown in FIG. 82.

Example 2: the organic electroluminescent device is prepared in the same manner as Example 1, except that the doping ratio in the light-emitting layer is changed as follows: Compound 1-1: TH: Compound 2-1=80%: 20%: 1%.

Example 3: the organic electroluminescent device is prepared in the same manner as Example 1, except that the doping ratio in the light-emitting layer is changed as follows: Compound 1-1: TH: Compound 2-1=60%: 40%:1%.

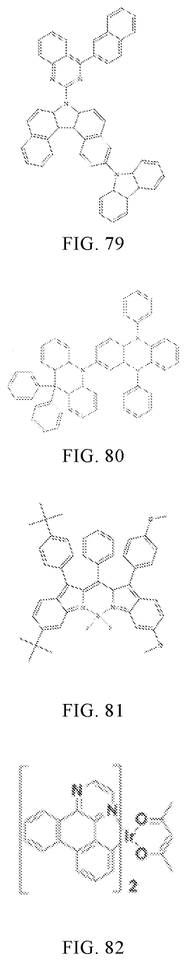

Example 4: the organic electroluminescent device is prepared in the same manner as Example 1, except that Compound 1-1 in the exciton separation layer and the light-emitting layer is replaced with Compound 1-2. The molecular structure of Compound 1-2 is shown in FIG. 79.

The test results are shown in the following table:

| | V (V) | CE (cd/A) | CIE | FWHM | LT₉₅ |
|---|---|---|---|---|---|
| Example 1 | 100% | 100% | (0.67, 0.33) | 39.3 | 100% |
| Comparative | 104% | 92% | (0.67, 0.33) | 39.3 | 83% |
| Example 1 | | | | | |
| Comparative | 96% | 94% | (0.67, 0.33) | 41.2 | 77% |
| Example 2 | | | | | |
| Example 2 | 98% | 113% | (0.67, 0.33) | 38.9 | 64% |
| Example 3 | 103% | 89% | (0.67, 0.33) | 39.3 | 118% |
| Example 4 | 99% | 92% | (0.67, 0.33) | 40.1 | 106% |

By taking Example 1 in the above table as an example and by comparing the organic electrode-emitting device provided in Example 1 with the organic electroluminescent devices provided in Comparative Examples 1 and 2, it can be seen that the organic electroluminescent device provided in the embodiment of the present disclosure has a significantly improved service life, and the luminous efficiency thereof can also be improved accordingly, such that the user experience can be enhanced.

In the second aspect, the embodiment of the present disclosure provides a display device, comprising the organic electroluminescent device as provided in any of the above embodiments. The display device may be an electronic device with display functions, such as a cell phone, a tablet computer, an electronic watch, a sports bracelet and a laptop computer. For the technical effects of the display device, reference may be made to the above discussion on the technical effects of the organic electroluminescent device, which will not be repeated here.

It would be understood that the above embodiments are merely exemplary embodiments adopted to illustrate the principles of the present disclosure, but the present disclosure is not limited thereto. It will be apparent to those skilled in the art that various modifications and improvements may be made without departing from the spirit and scope of the present disclosure, and such modifications and improvements are also considered as within the protection scope of the present disclosure.

1. An organic electroluminescent device, wherein the organic electroluminescent device comprises: a first electrode and a second electrode disposed opposite to each other, and a light-emitting layer disposed between the first electrode and the second electrode:
the light-emitting layer comprising: a first compound, a second compound and a third compound: wherein the first compound satisfies a first general formula; the third compound satisfies a second general formula; and the second compound has a difference between a triplet energy level and a singlet energy level of less than or equal to 0.3 eV;
the first general formula comprising: 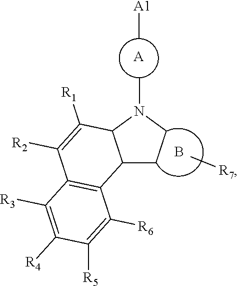
wherein the A ring denotes a substituted or unsubstituted C6 to C30 arylene group, or a substituted or unsubstituted C3 to C30 heteroarylene group;
the B ring represents phenyl, naphthyl, phenylene, naphthylene, phenanthryl, fluoranthenyl, pyridine ring, pyrazine ring, pyrimidine ring, pyridazine ring, triazine ring, substituted or unsubstituted alkyl chain, or substituted or unsubstituted C6 to C30 aryl or heteroaryl;
A1 represents phenyl, phenylene, naphthyl, naphthylene, dibenzofuran, dibenzothiophene, carbazole, pyrimidine ring, pyrazine ring, cyano, substituted or unsubstituted aryl or heteroaryl;
R1 to R7 are each independently selected from hydrogen, deuterium, a halogen group, a nitrile group, a nitro group, a hydroxyl group, a carbonyl group, an ester group, an imido group, an amino group, a substituted or unsubstituted C3 to C30 methylsilyl group, a substituted or unsubstituted boryl group, a substituted or unsubstituted C1 to C30 alkyl group, a substituted or unsubstituted C3 to C30 cycloalkyl group, a substituted or unsubstituted alkoxy group, a substituted or unsubstituted aryloxy group, substituted or unsubstituted alkylthio, substituted or unsubstituted arylthio, substituted or unsubstituted alkyl sulfonyl, substituted or unsubstituted C6 to C30 aryl sulfonyl, substituted or unsubstituted alkenyl, substituted or unsubstituted aryl alkyl, substituted or unsubstituted aryl alkenyl, substituted or unsubstituted alkyl aryl, substituted or unsubstituted alkyl amino, substituted or unsubstituted C1-C30 aryl alkyl amino, substituted or unsubstituted C6-C30 heteroaryl amino, substituted or unsubstituted C6-C30 aryl amino, substituted or unsubstituted C6-C30 aryl heteroaryl amino, substituted or unsubstituted C6-C30 arylphosphinyl, a substituted or unsubstituted phosphine oxide group, a substituted or unsubstituted C6 to C30 aryl group, or a substituted or unsubstituted heterocyclic group, or a substituted or unsubstituted (C1-C30)alkylbis(C6-C30)arylmethylsilyl group;
the second general formula comprising: 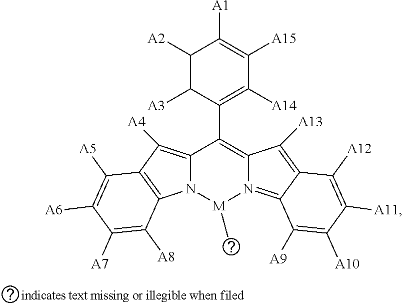
wherein M is selected from boron; n=1;
A1, A2, A3, A14, and A15 are each independently an aryl group having from 6 to 30 aromatic ring atoms, the aryl group being optionally substituted by one or more groups R1; wherein R1 may be an aldehyde group, a carbonyl group, a carboxyl group, a halogen atom, a sulfonic acid group, a haloalkyl group, cyano, nitro, a tertiary amino group, cyano, nitro, formyl, acyl, thiophene, dibenzothiophene, furan, dibenzofuran, cycloalkyl, aromatic alkynyl, a heterocyclic group, a halogen atom, alkoxy, aryl alkyl, methylsilyl, carboxyl, aryloxy, substituted amino, benzene, naphthalene, anthracene, phenanthrene, pyrene, fluoranthene, dihydropyrene, benzanthracene, isobenzothiophene, thiofluorene, pyrrole, indole, isoindole, carbazole, pyridine, quinoline, isoquinoline, acridine, phenanthridine, benzoquinoline, thienozine, or phenoxazine;
A5-A8, and A9-A12 are each independently a linear alkyl group having 1 to 10 carbon atoms, a branched or cyclic alkyl group having 3 to 10 carbon atoms, an alkenyl group, an alkynyl group, a substituted cycloalkyl group, an aromatic group, a substituted aromatic group, a fused ring aromatic group, a substituted fused ring aromatic group, a heterocyclic group, a substituted heterocyclic group; and
A4, and A13 are selected from linear or branched alkyl groups having from 1 to 10 carbon atoms, aromatic or heteroaromatic or fused rings having from 6 to 30 ring atoms.

2. The organic electroluminescent device according to claim 1, wherein the organic electroluminescent device further comprises: an exciton separation layer on a side of the light emitting layer close to the first electrode.

3. The organic electroluminescent device according to claim 1, wherein the overlap area between an emission spectrum of the first compound and an absorption spectrum of the second compound is greater than 5%.

4. The organic electroluminescent device according to claim 2, wherein the exciton separation layer comprises a fourth compound and a fifth compound; the fourth compound satisfying the first general formula; and the fifth compound having a difference between a triplet energy level and a singlet energy level of less than or equal to 0.3 eV, and the overlap area between an emission spectrum of the fourth compound and an absorption spectrum of the fifth compound is greater than 5%.

5. The organic electroluminescent device according to claim 2, wherein the organic electroluminescent device further comprises: a hole injection layer, a hole transport layer and an electron blocking layer disposed sequentially between the first electrode and the exciton separation layer in a direction away from the first electrode, and an electron injection layer, an electron transport layer and a hole blocking layer disposed sequentially between the second electrode and the light emitting layer in a direction away from the second electrode.

6. The organic electroluminescent device according to claim 5, wherein the third compound has a triplet energy level lower than the triplet energy level of the second compound.

7. The organic electroluminescent device according to claim 4, wherein the fifth compound has a triplet energy level lower than the triplet energy level of the fourth compound.

8. The organic electroluminescent device according to claim 5, wherein the absolute value of the LUMO energy level of the material of the electron-blocking layer differs from the absolute value of the LUMO energy level of the fourth compound by 0.3 eV or less.

9. The organic electroluminescent device according to claim 5, wherein the absolute value of the HOMO energy level of the material of the hole-blocking layer differs from the absolute value of the HOMO energy level of the third compound by more than 0.3 eV.

10. The organic electroluminescent device according to claim 2, wherein the light emitting layer has a thickness of less than or equal to 22 nm.

11. The organic electroluminescent device according to claim 2, wherein a doping ratio of the first compound to the second compound is 80%:20% to 60%:40.

12. The organic electroluminescent device according to claim 1, wherein the organic electroluminescent device further comprises: a light extraction layer located on a side of the second electrode away from the first electrode.

13. A display device, comprising the organic electroluminescent device as recited in claim 1.

14. The organic electroluminescent device according to claim 2, wherein the exciton separation layer comprises: a fourth compound and a fifth compound: the fourth compound satisfying the first general formula; and the fifth compound having a difference between a triplet energy level and a singlet energy level of less than or equal to 0.3 eV

15. The organic electroluminescent device according to claim 1, wherein the overlap area between an emission spectrum of the second compound and an absorption spectrum of the third compound is greater than 5%.

16. The organic electroluminescent device according to claim 5, wherein the triplet energy level of the second compound is lower than the triplet energy level of the first compound.

17. The organic electroluminescent device according to claim 5, wherein the triplet energy level of the first compound is lower than the triplet energy level of the material of the electron-blocking layer or the triplet energy level of the material of the hole-blocking layer.

18. The organic electroluminescent device according to claim 14, wherein the triplet energy level of the fourth compound is lower than the triplet energy level of the material of the electron-blocking layer or the triplet energy level of the material of the hole-blocking layer.

19. The organic electroluminescent device according to claim 2, wherein the exciton separation layer has a thickness of less than or equal to 3 nm.

20. The organic electroluminescent device according to claim 14, wherein a doping ratio of the fourth compound to the fifth compound is 80%:20% to 60%:40%.
